(19) United States
(12) Patent Application Publication
(10) Pub. No.: US 2003/0191999 A1
(43) Pub. Date: Oct. 9, 2003

(54) Integrated circuit that is robust against circuit errors

(75) Inventors: Richard Petrus Kleihorst, Eindhoven (NL); Renatus Josephus Van Der Vleuten, Eindhoven (NL); Nico Frits Benschop, Eindhoven (NL); Geeke Muurling, Vught (NL)

Correspondence Address: Corporate Patent Counsel, Philips Electronics North America Corporation, 580 White Plains Road, Tarrytown, NY, 10591, US

(73) Assignee: U.S. PHILIPS CORPORATION

(21) Appl. No.: 10/407,088

(22) Filed: Apr. 4, 2003

Related U.S. Application Data
(63) Continuation of application No. 09/822,446, filed on Mar. 30, 2001.

(30) Foreign Application Priority Data
Mar. 31, 2000 (EP) 00201182.3
Aug. 7, 2000 (EP) 00202788.6

(51) Int. Cl. G06F 11/00; G01R 31/28

(52) U.S. Cl. 714/735

(57) ABSTRACT

Errors are corrected that occur in the operation of a combinatorial logic circuit in an integrated circuit.

The combinatorial circuit computes a vector of intermediate signals from the input signal. The combinatorial logic circuit is designed so that, when the combinatorial logic circuit operates without error, the vector belongs to an error correcting code, not being a repetition code. The combinatorial logic circuit comprises combinatorial logic sections, each for computing a respective one of the intermediate signals independently from the other sections. An error correction circuit computes an output signal from the vector, with a computation that maps erroneous vectors to the output signal for a nearest correct vector from the error correcting code when these erroneous vectors differ from the correct vector in less than a predetermined number of the intermediate signals.

Defects are a major problem in digital integrated circuits. To avoid use of integrated circuits that generate erroneous signals, integrated circuits are extensively tested after manufacture and all integrated circuits that are found to be defective are discarded. Any small defect may cause the integrated circuit to generate erroneous digital signals. This problem increases as integrated circuits become more complex. Thus, testing and discarding increasingly raises the cost of integrated circuits, in terms of lost silicon and lost testing time. Moreover, testing does not prevent “soft” errors during use, for example due to alpha particles or excessive noise.

For digital integrated memories, this problem is addressed by storing words in an error correcting code. When an error correcting code is used, not all possible binary words are stored in the memory, but only a subset of all possible words. The words in this subset are termed the words “in” the error correcting code. The words in the error correcting code differ from each other at least at “h” bit positions (h being at least three). When a word is read out of memory and it is not a word in the subset, the word is corrected to the word in the subset that differs at the least number of bit positions. Thus, the bit errors are corrected if the number of bit errors is less than h/2.

This approach is limited to the correction of errors in words stored in a memory. Errors in an address decoder, for example, are not prevented in this way. Nor does this approach apply to “combinatorial logic” circuits, that is, circuits that logically compute an output signal from an input signal using some combinatorial logic function, rather than retrieving the entire signal from memory.

Error correcting codes are also used for protection against errors in a transmission circuit. In a circuit made up of an encoder, a decoder and a transmission circuit between the encoder and the decoder, encoded data is transmitted (copied) from the encoder to the decoder by the transmission circuit. The encoder uses an error correction code that makes it possible to reconstruct the input signal of the encoder from the output of the transmission circuit. The decoder corrects errors that have arisen in the transmission circuit.

This approach is intended for correction of errors in transmission circuits, that is, circuits with straightforward input/output relations, so that the input may be recovered from the output. Errors arising during transmission through a circuit with a more complex input/output relation cannot be corrected in this way if the input/output relation of the circuit disturbs the error correcting capability of the code. This is the case for example if the output depends only on the AND and/or OR of some of some of the input bits. Generally, inputting input signals in an error correcting code is no solution for correcting errors that arise during transmission through arbitrary combinatorial logic circuits with arbitrary input/output relations that involve AND's and OR's etc. of input bits.

The error correction problem for arbitrary circuits has been solved in the art by the use of the so-called majority voting technique. Majority voting allows for the correction of errors in digital circuits in general. To apply majority voting, a number of identical copies of the circuit is used, each receiving the same input. As a result, barring errors, all copies will output the same output signal. Formally speaking this means that the output signals are code words of a so-called repetition code, wherein each bit of the output occurs repeatedly. If the output signals differ, the signal that is output by the majority of the copies is used as digital output. Thus, if any one or a minority of the copies generates an erroneous signal, this signal is suppressed at the output. Majority voting solves (or at least reduces) the problem of errors for any logic circuit, but at the expense of considerable overhead, since at least three copies of the circuit need to be implemented for a minimum of error correction capability.

Amongst others, it is an object of the invention to make it possible to generate error corrected signals from combinatorial logic circuits that are more complicated than transmission circuits, the error correction requiring less overhead than needed for majority voting.

A method according to the invention is set forth in claim 1 and a circuit according to the invention is set forth in claim 4. In the circuit according to the invention, errors are corrected that are caused by a combinatorial circuit that computes a complex combinatorial function. The combinatorial logic circuit is made up of mutually independent sections, each for generation an intermediate signal in parallel with the other sections. The combination of all sections is designed so that, if the sections operate without any errors, the bits of the output signal form code words in an error correcting code. The number of the sections is larger than the number of output signals that is actually needed, but by using other codes than a repetition code, for example a hamming code, the number of section is less than three times the number of output signals. An error in one section results in an error in only one intermediate signal, which is corrected by an error correcting circuit. Normally, combinatorial logic circuits are designed to minimize silicon area, circuits that produce different output bits sharing as much logic as possible in order to minimize silicon area. In this respect, the use of independent sections implies increased silicon usage, but it has been found that the cost of this increase is smaller than the cost of lost of silicon area if combinatorial logic circuits have to be discarded due to errors.

It should be noted that the claimed combinatorial logic circuit is not a conventional encoder for an error correcting code, in that the claims concern a combinatorial logic circuit whose input/output relation is not invertible. This means that it is not generally possible to determine the input signal from the output of the combinatorial logic circuit, even if the combinatorial logic circuit operates without errors. The invention applies to functions of the combinatorial circuit so that several different values of the input signals may result in the same output of the combinatorial logic circuit and the same output of the circuit overall, even if the circuit operates without error. This is in contrast to the input/output relation of an encoder for an error correcting code, which is necessarily invertible to allow unequivocal reconstruction of the input from the output when the circuit operates without error.

In an embodiment, a first part of the sections produce information bits, for use by other circuits, and a second part of the sections produce error correction bits, for the detection and correction of errors in the information bits. Starting point for the design of such a circuit is the input/output relation needed for generating the information bits. This is a matter of the desired logic function and depends on the particular circuit being designed. The input/output relations of the sections that produce error correction bits are derived from this by composing functions corresponding to computation of the information bits followed by computation of error correction bits from the information bits.

Thus, each section that produces an error correction bit performs a function corresponding to computation of intermediate signals equal to the output signals of the sections that compute information signals, followed by computation of an error correction signal from the intermediate signals. However, this does not mean that logic circuits are required for computing all intermediate signals in the sections that produce error bits. The circuit in each such section as a whole is optimized so as to minimize the amount of silicon area. It has been found that the required silicon area for the section is usually much less than if the circuits for computing the intermediate signals and the error correction signal were optimized separately.

In general, the combinatorial logic circuit, when operating without errors, will only be able to produce those output signals that are needed at the output. It is not able to form unneeded signals, whatever its input signals. This means that not all possible vectors of the error correcting code will be produced. In particular, if one considers the possible values of each information signal individually, then the combinatorial logic circuit will not produce all signals from a hypothetical space of possible information signals obtained by taking the Cartesian product of those spaces (i.e. the space obtained by combining possible values of output signals of different information signal sections, disregarding whether these signals occur for the same input signal).

In an embodiment of the invention, the integrated circuit contains sections with multiple outputs. When logic gate in such a section doesn't function properly several of the outputs may be in error as a result. Thus, a single circuit error may cause several erroneous signals. In this embodiment the integrated circuit contains multiple layers of error correction in which input bits from different combinations of sections are combined. This makes it possible to correct such circuit errors.

These and other advantageous aspects of the invention will be described in more detail using the following figures.

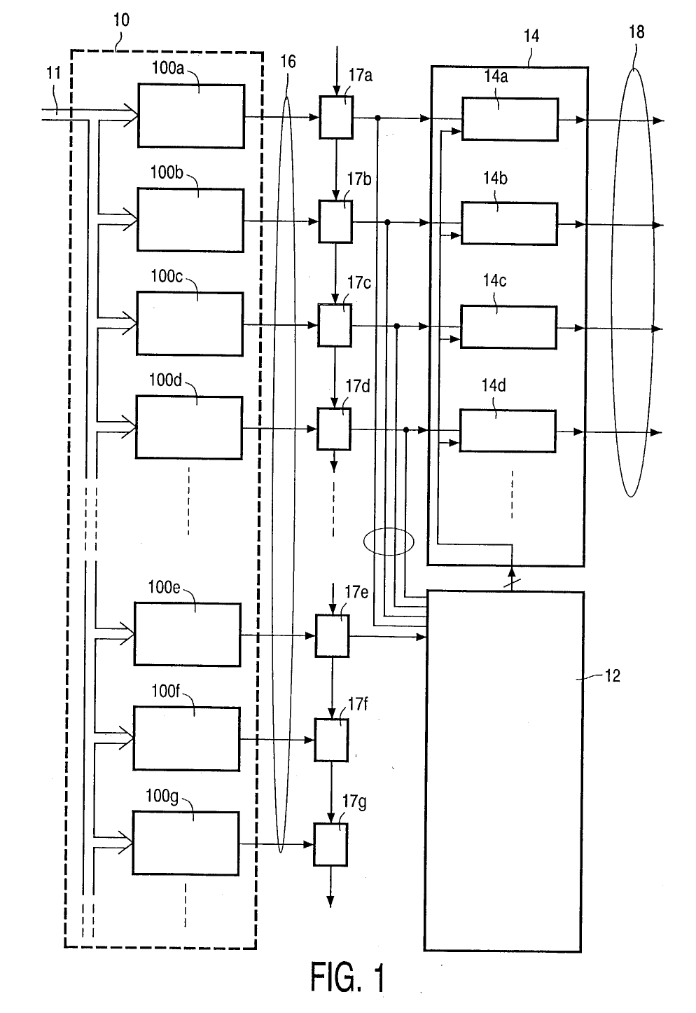

FIG. 1 shows a circuit with a correction circuit for correcting circuit errors

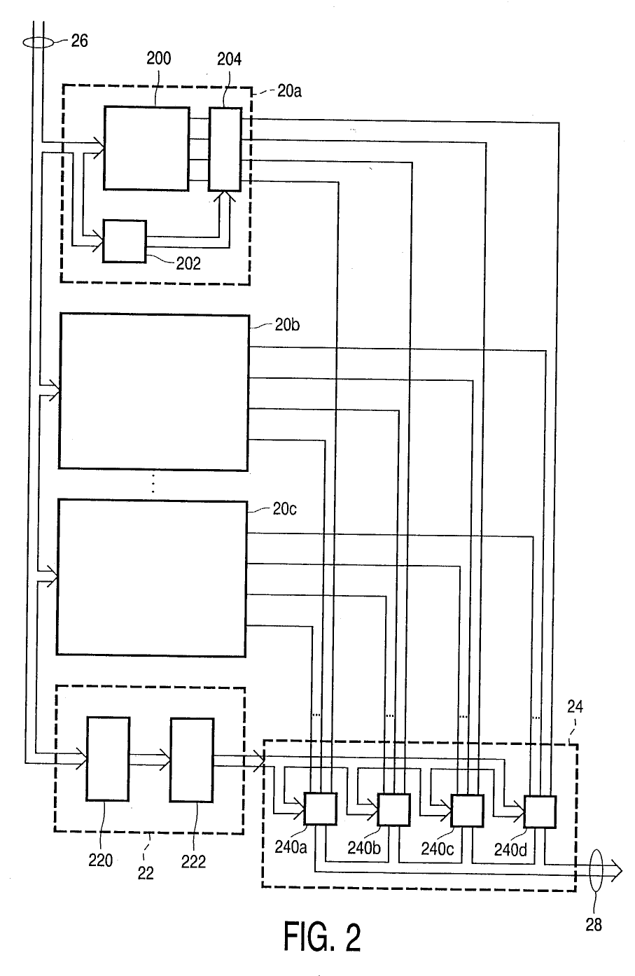

FIG. 2 shows a two layer circuit with a correction circuit for correcting circuit errors

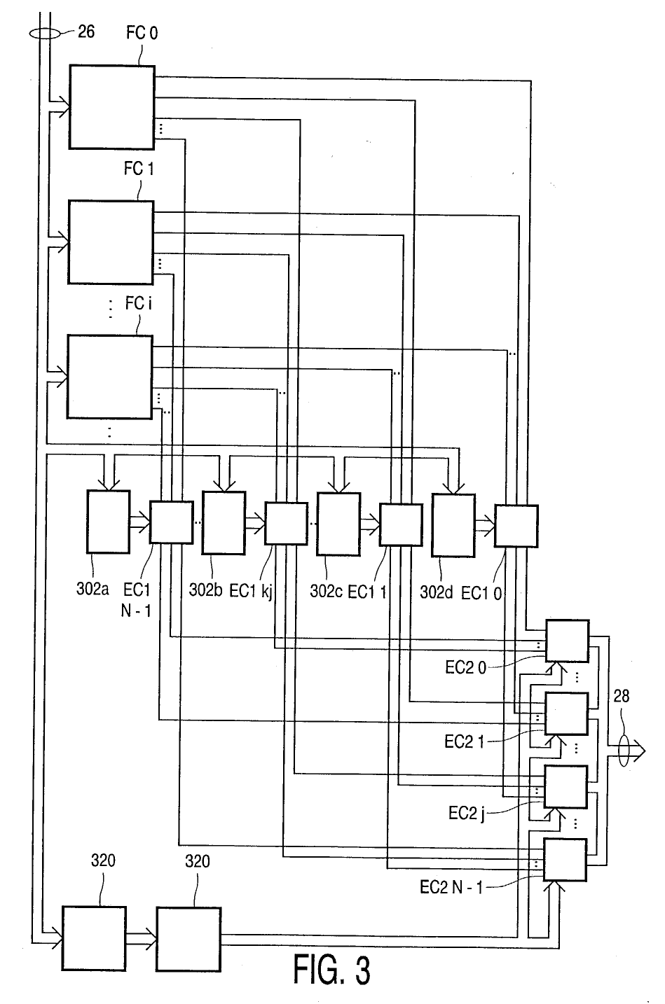

FIG. 3 shows a further two layer circuit with a correction circuit for correcting circuit errors

FIG. 1 shows a circuit comprising a combinatorial logic circuit 10 with combinatorial logic functionality, a correction determination circuit 12 and a correction circuit 14 and a number of scan chain registers 17a-g. The combinatorial logic circuit 10 is made up of a number of independent sections (of which only a number 100a-g is shown explicitly for simplicity). The sections 100a-g have inputs coupled to a common input 11. The outputs of the sections together form a vector output interface 16 which is coupled to an input of the correction determination circuit 12 via scan chain registers 17a-g. The correction circuit 14 comprises correction sections (of which only three 140a,b,c are shown explicitly for simplicity). The number of sections 100a-g in the combinatorial logic circuit 10 is larger than number of correction sections 140a-d, to provide for redundancy that allows correction of errors. Outputs of a subset of the sections of the combinatorial logic circuit 10 are coupled to inputs of respective ones of the sections of the correction circuit 14. The correction determination circuit 12 has outputs coupled to respective ones of the correction sections 140a-d. The outputs of the sections 140a-d of the correction circuit 14 together form the output 18 of the circuit.

The combinatorial logic circuit 10 has a complex input/output relation, realized by a considerable amount of circuitry, which is prone to suffer from manufacturing errors.

In operation, the sections 100a-g of the combinatorial logic circuit 10 compute respective digital intermediate output bits. In one example, these output bits include “function” bits and “error correction” bits, computed by the sections 100a-d that are connected to the correction circuit 14 and by the remaining sections 100e-g respectively. The function bits are computed according to the I/O relation between the input 11 and the output 18, that is required of the circuit. The error correction bits are computed so that the output bits of the sections 100a-g together form a vector from an error correcting code. An error correcting code is defined in this example by the fact that the error correction bits correspond to a function of a vector made up of the function bits, the function being selected so that if two vectors differ at x (>0) bits, the corresponding vectors of error correction bits differ at least by 2*t+1−x bits (if x<2*t+1; otherwise, if x>=2*t+1, any error correction bits, including identical error correction bits may be used). “t”, here, is a positive integer representing the number of bit errors that can be corrected. Such functions of the function bits are known per se from the field of error correcting codes. For example, one may use a one bit (t=1) error correcting hamming code. More generally, an error correcting code is defined by the fact that any two vectors from the code are either identical or differ at at least 2*t+1 bits.

It should be noted that although the outputs from the sections 100a-g together form vectors from an error correcting code, it is by no means necessary that the sections 100a-g can form all vectors from that error correcting code in response to input signals. For example, although the vector 0000000 might be in the error correcting code, the sections 100a-g will not be able to form the bits of this vector if the output 0000 is not needed from the function bits.

The correction determination circuit 12 determines a correction that is needed to correct the vector at the output of the sections 100a-d that produce the function bits, assuming that the number of errors does not exceed the error correcting capacity of the error correcting code. The correction circuit 14 uses the corrections that have been determined by the correction determining circuit 12 to correct the bits output by the sections 100a-d of the combinatorial logic circuit. Each section 140a-d of the error correction circuit 14 is for example an “exclusive or” gate.

Under normal circumstances, the combinatorial logic circuit 10 operates as designed, without any errors. In this case, no correction is needed and the correction circuit passes the function bits output by the sections 100a-d. However, if the combinatorial logic circuit does not operate as designed, but the number of errors does not exceed the error correcting capacity of the code, the correction determination circuit 12 and the correction circuit 14 ensure that the signal at the output 18 is nevertheless as designed.

Scan chain registers 17a-g are optional. If inserted in the circuit, they allow testing of the function of the combinatorial logic circuit 10 according to a conventional scan test technique. Additionally, the registers may be used for pipelining the operation of the circuit (the function of the combinatorial logic circuit 10, and error correction circuit 12 being performed in different clock cycles), but if this is not desired, the registers 17a-g may be left transparent if the circuit is not in test mode. A scan test will show whether there are any errors in the combinatorial circuit 10 before any error correction. This allows a classification of circuits into circuits that are error free, circuits that have too many errors to be corrected by the error correction circuit 14 and circuits that are not error free, but whose errors can be corrected. The first and third type of circuit may be sold as different quality products, the former being suitable for operation in a more hostile environment (subject to alpha particles for example). By inserting scan chain registers (not shown) behind the output 18 of error correction circuit 14 as well, the operation of the error correction circuit 14 and correction determination circuit 12 can be tested as well, separately from the combinatorial logic circuit 10. Generally, scan chain registers (not shown) are inserted at the input, in front of combinatorial logic circuit 10 as well, to control the test patterns supplied to the combinatorial logic circuit during test. But if the input is accessible in another way (for example directly via IC pins) test patterns may also be supplied to the combinatorial logic circuit without a scan chain.

A one-bit error correcting hamming code may be used, but the invention is not limited to any specific error correcting code. Numerous correction determination and correction circuits known from the considerable literature on error correction can be used in the circuit of FIG. 1. These circuits are known for a transmission systems, where the correction bits are computed from the function bits, and transmitted with the function bits, so that the correction bits can be used to correct errors in the function bits that have occurred in the course of transmission of the function bits. In the present invention, however, the error correcting code is used to correct errors that occur during the computation of the function bits in the combinatorial logic circuit 10, not necessarily to correct errors that occur during transmission. The combinatorial logic circuit 10 is preferably coupled directly to the correction determination circuit 12 and the correction circuit 14, i.e. via a connection that will not generate so many errors as to justify the error correction code that is used.

Correction of computation errors requires more precautions than correction of transmission errors. To be able to correct circuit errors, first of all, the sections 100e-g that compute error correction bits compute the error correction bits from the input 11 of the combinatorial logic circuit 10, not from the outputs of the sections 100a-d that compute the function bits. Thus, each section 100e-g that computes an error correction bit performs a function equivalent to copying the computation of the function bits, followed by computing an error correction bit from the result of the copied computation of the function bits (In contrast, for correcting errors during transmission, the error correction bits could be computed from the information bits). At first sight, this may appear to require that the sections 100e-g that compute the error correction bits contain copies of the sections 100a-d for computing the function bits. However, this is not generally the case, because only the error correction bits and not the function bits are needed from the section for computing the error correction bits. The circuitry in the sections 100e-g that compute the error correction bits is optimized to perform this computation as a whole, i.e. each for performing the computation of a single error correction bit. These sections 100e-g do not consist of individually optimized parts that compute the function bits and the error correction bits respectively. This means that in general no copy of each and every information signal will be present in the sections 100e-g that compute the error correction bits. As a result, each section 100e-g is generally much smaller than a circuit that computes the function bits and the error correction bits separately.

Secondly, the combinatorial logic circuit 10 of which the errors must be corrected is split in independent sections 100a-g, each for computing a different one of the bits at the output 16. This avoids the situation where a shared circuit is used in the computation of more than one output bit at output 16. The latter situation could make a circuit error result in multiple bit errors. Thus, by avoiding shared circuits, it is ensured that no single circuit error in the combinatorial logic circuit of which the errors must be corrected results in more than one bit error at the output 16 of the combinatorial logic circuit 10.

The correction determination circuit 12 receives both the computed function bits and the computed error correction bits from the sections 100a-g of the combinatorial logic circuit 10. From these function bits and error correction bits, correction determination circuit 12 computes corrections for the function bits, which it supplies to the error correction circuit 14 to correct the function bits, if necessary, before passing them to the output 18.

In combination, the correction determination circuit 12 and the error correction function to detect whether or not the combined outputs of the sections 100a-g that produce the function bits and the error correction bits is one of a number of possible combined outputs that can occur when the sections 100a-g operate properly. If not, a correction is determined that corrects the output of the sections 100a-g to the nearest possible output value that can occur when the sections 100a-g operate properly, at least if the number of sections that is in error is not too great.

Again, numerous error correction schemes are known from the art of error correcting codes for correcting errors during transmission. This art provides functional descriptions of the relation between bits that have to be corrected and error correction bits, as well as functional descriptions of the relation between received bits and the correction. In the invention these functional descriptions are applied to the design of the sections 100e-g that compute error correction bits and to the correction determination circuit 12. Of course, any errors that occur in the correction determination circuit 12 itself will not be corrected. Therefore, correction determination circuit 12 is preferably kept as simple as possible. In an embodiment, this is realized by using linear error correcting codes. With a linear error correcting code the correction determination circuit can be kept small.

In a linear error correcting code, every error correction bit is a weighted sum of function bits (in the field of numbers 0, 1 where addition corresponds to exclusive or and multiplication to logic AND). Thus, each error correction bit corresponds to a weight vector, with components for respective function bits. The components have a value of one or zero, as pertinent for each function bit for the relevant error correction bits. As a result, in a section 100e-g that computes an error correction bit, only those copies of function bits contribute for which the corresponding component for that error correction bit is 1. The error correction bit is an exclusive OR of those function bits. The section 100e-g that computes this error correction bit performs the function equivalent to computing those function bits and taking their exclusive OR. The computation of the exclusive OR may be integrated with the computation of the function bits in the section. This makes it possible to optimize the section so that it requires with a minimum of silicon area. A truth table can be formed for the exclusive OR of the relevant function bits as a function of the input values of the section and a minimum circuit for realizing that truth table can be used.

Similarly, with a linear error correcting code, error correction involves computing weighted sums of function bits and error correction bits, that is, an exclusive OR of a subset of the function bits and the error correction bits. This computation can be realized with relatively few circuits.

Of course, a linear error correcting code is only one example of an error correcting code from which vectors (generally a subset of vectors) may be used to implement the invention. Non-linear codes may also be used. Also, although FIG. 1 shows an embodiment that uses a systematic code (i.e. a code in which a subset of the bits produced by the sections 100a-g of the combinatorial logic circuit 10 correspond directly to the bits at the output if the section do not produce any error), the invention is not limited to systematic codes. Non-systematic codes may also be used in which a non-zero the outputs of the sections 100a-g are modified to produce the output 18 of the circuit even if there is no error.

The only thing that matters is that the correction determination circuit 12 and the correction circuit 14 together function to convert signals at the vector output interface 16 to signals at the output 18 according to an error correction function. An error correction function, here, is defined as a function that produces the same result for different argument vectors that mutually differ only at a limited number of positions (section outputs) from a correct vector. At the same time, the combinatorial logic circuit 10 must correspond to the combination of the correction determination circuit 12 and the correction circuit 14, in the sense that, when the combinatorial logic circuit functions as designed, it must produce only the mentioned “correct vectors”, which differ at less than a limited number of positions from the different argument vectors that all result in the same corrected output. Hence, the independent sections 100a-g of the combinatorial logic circuit 10 must be adapted to each other so that together they produce only those “correct vectors”, when they operate as designed. This is realized for example by designing a number of sections 100e-g for producing error correction bits, each with the function of computing an error correction bit from copies of the function bits.

Also, although FIG. 1 illustrates the invention by means of sections 100a-g that each have a single bit as output, but without deviating from the invention sections with multi-bit outputs may be used. This can be done for example in combination with known error correcting codes for correcting erroneous numbers in a set of numbers, each from a range that includes more than two values.

FIG. 2 shows a circuit with two layers of error correction. The circuit contains first function blocks 20a-c (three function blocks are shown by way of example, but any number may be present), an overall error correction bit generator 22 and an overall error correction circuit 24. The input 26 of the circuit is coupled to the first function blocks 20a-c and the error correction bit generator 22. Outputs of the function blocks 20a-c and the overall error correction bit generator 22 are coupled to the overall error correction circuit 24. An output of the overall error correction circuit 24 forms an output 28 of the circuit.

A first one 20a of the function blocks 20a-c is shown to contain a functional circuit 220, a local error correction bit generator 202 and a local error correction circuit 204. The input 26 is coupled to the functional circuit 220 and the local error correction bit generator 222. The outputs of the functional circuit 220 and the local error correction bit generator 222 are coupled to the local error correction circuit 224. An output of the local error correction circuit 224 is coupled to an input of the error correction circuit 24. The other function blocks 20a-c preferably all have the same general structure as the first one 20a of the function blocks, each containing a functional circuit, a local error correction bit generator and a local error correction circuit. The functional circuits 200 in different blocks 20a-c have mutually different internal structures, according to a required function of the circuit. In general, the functional circuits contain a collection of interconnected logic gates (not shown), different ones of the outputs of the functional circuit 200 depending on the output of common logic gates in the functional circuit 200.

The overall error correction bit generator 22 contains an overall error correction bit generator circuit 220 and an error correction bit correction circuit 222. The input 26 is coupled to an input of the overall error correction bit generator circuit 220, which in turn has an output coupled to the error correction bit correction circuit 222. An output of the error correction bit correction circuit 222 is coupled to the error correction circuit 24.

The overall error correction circuit 24 contains a number of partial error correction circuits 240a-d (by way of example four of such partial error correction circuits are shown). The outputs of the function blocks 20a-c and the overall error correction bit generator 22 each comprise a number of bit outputs. Different groups of the bit outputs from a function block 20a-c (typically groups made up of one bit only) are coupled to a respective ones of the partial error correction bits. The same holds for different groups of bit outputs of the overall error correction bit generator 22, except that typically more than one bit is included in each group. Each partial error correction circuit 240a-d receives inputs from groups of bits of all of the function blocks 20a-c and the overall error correction bit generator 22.

In operation, the functional circuit 220 produces an output that is some logic function of signals received at its input 26, as required by the function that the circuit has to perform. For this purpose, functional circuit 220 contains a collection of interconnected logic gates (not shown). Local error correction bit generator 202 computes error correction information from the signals received at the input 26. The local error correction bit generator has been designed so that when both the functional circuit 220 and local error correction bit generator 222 operate as designed, the combined outputs of functional circuit 220 and local error correction bit generator 222 form vectors in an error correcting code. That is, different possible output vectors differ from each other at at least a predetermined number of bit positions. Local error correction circuit 224 passes the output signal of functional circuit 220 unmodified when the output signal of the combination of functional circuit 220 and local error correction bit generator 222 is a vector in the error correcting code. If this is not the case, this is due to an error in the operation of the functional circuit 220 and/or local error correction bit generator 222. Local error correction circuit 224 then determines a corrected vector in the error correcting code that differs at the least number of bit positions from the vector output by functional circuit 220 and local error correction bit generator 222, or at least local error correction circuit 224 determines the part of that corrected vector that corresponds to the output of the functional circuit 220. Local error correction circuit 224 outputs this part of the corrected vector.

Overall error correction bit generator 22 generates error correction bits so that the combined outputs of the function blocks 20a-c and the overall error correction bit generator 22 form vectors in an overall error correcting code if the function blocks 20a-c and the overall error correction bit generator 22 function as designed, or at least if the local error correction circuit 224 and any of its equivalents in the function blocks 20a-c are able to correct errors in the functional circuit 220 and corresponding functional circuits in other function blocks 20b-c. In case of FIG. 2, these vectors are made up of a number of sub-vectors (as many sub vectors as there are partial error correction circuits 240a-d), where each subvector is in an error correcting code of its own. Each sub-vector contains groups of bits (each group typically made up of one bit) from all of the function blocks 20a-c and a group of bits from the overall error correction bit generator 24.

Error correction circuit 24 corrects errors in the vector produced by the function blocks 20a-c. Each partial error correction circuit 240a-d corrects errors in the groups bits supplied to it. The corrected outputs of the partial error correction circuits 240a-d, or at least the part of these outputs corresponding to bits from the function blocks 20a-c, together form the output 26 of the overall error corrected circuit.

Because the output bits of the function blocks 20a-c are distributed over different partial error correction circuits 240a-c, it is possible to correct a major error in any one of the function blocks (that is, an error that affects a large number or even all of the output bits of that function block 20a-c). Therefore, functional circuits in the function blocks 20a-c, like functional circuit 200, need not be split into independent sections so as to avoid such major errors. Error correcting capability is obtained in this case because the function blocks 20a-c are independent.

Without deviating from the invention, the overall error correcting circuit 24 may also be inserted between the functional circuit 200 and the local error correction circuit 204 in the first function block (and similarly between similar circuits in the other function blocks). This allows for correction of major errors in a function block by means of the partial error correction circuits 240a-c before correction of errors by the local error correction circuits 204 etc.

Of course, pipelining registers (not shown) may be inserted in the circuit, for example between on one hand the function blocks 20a-c and the overall error correction bit generator 22 and on the other hand the overall error correction circuit 24, and/or between on one hand the functional circuit 200 and the local error correction bit generator 202 and on the other hand the local error correction circuit 204 (and at equivalent positions in the other function blocks 20b,c). Registers in each one or both of these positions can also be used for testing to discriminate between circuits that function without error and functions in which errors are corrected.

FIG. 3 shows a circuit that is similar to the circuit of FIG. 2, except that bit outputs of each functional circuit FC 0, FC 1, FC i (i symbolizing an index, to indicate that there may be any number of functional circuits) are distributed over different “local” error correction circuits EC1 1, EC1 2, EC1 j, EC1 N, each error correction circuit receiving one output bit from each different functional circuit FC 0, FC 1, FC i. (In the context of FIG. 3, the “local” error correcting circuits EC1 1, EC1 2, EC1 j, EC1 N will be referred to as “first-layer error correcting circuits”; in the embodiment of FIG. 3 these circuits are not local to specific ones of the functional circuits FC 0, FC 1, FC i). Error correction bit generator circuits 302a-b coupled tot the input have been included for each error correction circuit EC 1 1, EC1 2, EC1 j, EC1 N−1 of the first layer and an error correction bit generator circuit 320 followed by an error correction bit error correction circuit 322 has been provided for the error correction circuits EC2 1, EC2 2, EC2 j, EC2 N−1 of the second layer. The error correction circuits ECI 1, EC1 2, EC1 j, EC1 N−1 of the first layer are connected so that the outputs of different ones of the first layer error correction circuit ECI 1, EC1 2, EC1 j, EC1 N−1 that correspond to output bits from the same functional circuit FC 0, FC 1, FC i (if there is no error) are again connected to different partial error correcting circuits EC2 0, EC2 1, EC2 j, EC2 N-1. (In the context of FIG. 3, the “partial” error correcting circuits EC2 1, EC2 2, EC2 j, EC2 N−1 will be referred to as “second-layer error correcting circuits”).

The connections between the outputs of the functional circuits FC 0, FC 1, FC_i in the embodiment of FIG. 3, are as described in table I

TABLE I

| | FC 0 | FC 1 | FC i |
|---|---|---|---|
| EC1 0 | 0 | 0 | 0 |
| EC1 1 | 1 | 1 | 1 |
| EC1 j | j | j | j |
| EC1 N − 1 | N − 1 | N − 1 | N − 1 |

In table I, it is assumed that N labels 0,1 . . . j, . . N−1 have been assigned to the individual bit outputs of each functional circuit FC 0, FC 1, FC i. The entries in the table indicate the label of the output of the functional circuit FC 0, FC 1, FC i that is connected to the error correction circuit EC1 0, EC1 1, EC1 j, EC1 N−1 at the head of the row.

Table II describes the connections between the first layer of error correction circuits EC1 0, EC1 1, EC1 j, EC1 N−1 and the second layer of error correction circuits EC2 0, EC2 1, EC2 j, EC2 N−1.

TABLE II

| | FC 0 | FC 1 | FC i |
|---|---|---|---|
| EC2 0 | 0 | 1 | i |
| EC2 1 | 1 | 2 | i + 1 mod N |
| EC2 j | j | j + 1 | i + j mod N |
| BC2 N − 1 | N − 1 | 0 = N mod N | i + N − 1 mod N |

In table II, the outputs of the first layer of error correction circuits EC 1 0, EC1 1, EC1 j, EC N−1 are indicated by means of the bit output of the functional circuit FC 0, FC 1, FC i from which that output depends when there is no circuit error. At the head of the columns the functional circuits FC 0, FC 1, FC i are identified and the entries in the table identify the labels (0, 1, . . . j, . . . ) of the bit outputs of those functional circuits FC 0, FC 1, FC i.

By way of simplified illustration FIG. 3 shows only the signal lines corresponding to the functional circuits FC 0, FC 1, FC i that are shown, and their connection to the error correction circuits EC . . . , EC2 . . . . In practice, there may be more or fewer functional circuits and/or there may be more or fewer error correction circuit in each layer. The error correction circuits may have more or fewer connections (For example, FIG. 3 shows three functional circuits FC 0, FC 1, FC i, and consequently only three connections from each error correction circuit EC 1 in the first layer to four error correction circuits EC2 in the second layer. But when there are more functional circuits and each error correction circuit of the first layer has more inputs and more outputs, more connections will be made from each error correction circuit EC1 in the first layer to the second layer of error correction circuits EC2).

Of course the connections of the embodiment of FIG. 3 are only an example of the principle that outputs of the first layer error correction circuit EC1 1, EC1 2, EC1 j, EC1 N−1 that correspond to output bits from the same functional circuit FC 0, FC 1, FC i (if there is no error) are again connected to different partial error correcting circuits EC2 0, EC2 1, EC2 j, EC2 N−1.

When error correction circuits are connected so that different outputs of the first layer of error correction circuits EC1 1, EC1 2, EC1 j, EC1 N−1 that correspond to outputs bits from the same functional circuit FC 0, FC 1, FC i (if there is no error) are again connected to different error correction circuits in the second layer of error correction circuits EC2 1, EC2 2, EC2 j, EC2 N−1, the inputs of each error correction circuits in the first and second layer EC1 1, EC1 2, EC1 j, EC1 N−1, EC2 1, EC2 2, EC2 j, EC2 N−1 receive inputs from independent functional circuits FC 0, FC 1, FC i. As a result, a major error in any pair of the functional circuits FC 0, FC 1, FC i never leads to more than a correctable number of errors at the input of any single error correcting circuit EC1 1, EC1 2, EC1 j, EC1 N−1 in the first layer or any single error correcting circuit EC2 1, EC2 2, EC2 j, EC2 N−1 in the second layer. Therefore, simultaneous major errors from different functional circuits FC 0, FC 1, FC i will be corrected.

It will be noted that the first layer of error correction circuits EC1 0, EC1 1, EC1 j, EC1 N−1 on its own already is capable of correcting any major error in any single one of the functional circuits FC, operating according to the embodiment shown in FIG. 1, applied a number of times to different output bits. Hence a circuit without the second layer of error correction circuits EC2 0, EC2 1, EC2 j, EC2 N−1 is useful in itself. Adding the second layer as shown in FIG. 3 provides additional error correction capability in that in enables the correction of more errors, including major errors in multiple functional circuits FC 0, FC 1, FC 2.

Of course, pipelining registers (not shown) may be inserted in the circuit, for example between on one hand the functional circuits FC 0, FC 1, FC i and the error correction bit generators 302a-d and on the other hand the first layer of error correction circuits EC1 0 . . . N−1, and/or between on one hand the first layer of error correction circuits EC1 0 . . . N−1 and the error correction bit generator 320 and on the other hand the second layer of error correction circuits EC2 0 . . . N−1. Thus, input signals from different successive processing cycles may be processed in parallel in the functional circuits FC 0, FC 1, FC i, the first layer of error correction circuits EC1 0 . . . N−1 and the second layer of error correction circuits EC2 0 . . . N−1. Registers in each one or both of these positions can also be used as part of a scan chain for testing to discriminate between circuits that function without error and functions in which errors are corrected.

As in FIG. 1, the error correction bit generator circuits 202, 220, 302a-d, 320 of FIGS. 2 and 3 perform a function corresponding to computation of intermediate signals equal to the output signals of the functional circuits FC 0, FC 1, FC i, followed by computation of an error correction signal from the intermediate signals. Functional circuits FC 0, FC 1, FC i, can be complicated circuits, involving non-invertible logic combination of input signals. However, this does not mean that logic circuits are required in the error correction bit generator circuits 202, 220, 302a-d, 320 for computing copies of the output signals of the functional circuits FC 0, FC 1, FC i, since these signals are not required at any output of the error correction bit generators 202, 220, 302a-d, 320. The circuit in each error correction bit generator 202, 220, 302a-d, 320 may be optimized so as to minimize the amount of silicon area. In general, copies of all the output signals of the functional circuit FC 0, FC 1, FC i that are involved in the definition of the error correction bits will not be generated in the error correction bit generators 202, 220, 302a-d, 320 for generating those error correction bits. It has been found that as a result the required silicon area for the section is usually much less than if the circuits for computing copies of the output signals of the functional circuits FC 0, FC 1, FC i and the error correction bits were optimized separately.

1. A method of correcting errors that occur in the operation of a combinatorial logic circuit in an integrated circuit, the method comprising the steps of
supplying an input signal;
computing a vector of intermediate signals from the input signal using the combinatorial logic circuit, the combinatorial logic circuit being designed so that, when the combinatorial logic circuit operates without error, the vector belongs to an error correcting code, not being a repetition code, a logic relation between the input signal and the vector from the error correcting code being non-invertible, the combinatorial logic circuit comprising combinatorial logic sections, each for computing a respective one of the intermediate signals independently from the other sections;
computing an output signal from the vector, with a computation that maps erroneous vectors to the output signal for a nearest correct vector from the error correcting code when these erroneous vectors differ from the correct vector in less than a predetermined number of the intermediate signals.

2. A method according to claim 1, wherein the output signal comprises component signals, each being a function of a respective one of the intermediate signals only when the combinatorial logic circuit operates without error, and wherein the output signals are a non-invertible combinatorial function of the input signal when the combinatorial circuit operates without error.

3. A method according to claim 2, wherein the error correcting code is an error correcting code suitable for correcting all vectors from a product space corresponding to a Cartesian product of signal spaces of possible values for the components signals of the output signal individually, the combinatorial logic circuit mapping an input space of possible values of the input signals to a proper subset of the product space.

4. An integrated circuit comprising
an input;
mutually independent sections, each section being coupled between the input and a respective intermediate output, the sections providing a logic relation between digital input signals at the input and digital intermediate signals at the intermediate outputs, where the logic relation implemented by the sections in combination implement a non-invertible combinatorial function, the sections being designed so that, when the sections operate properly, the digital intermediate signals of the intermediate outputs in combination form a vector in an error correcting code, not being a repetition code;
an error correction circuit coupled between the intermediate outputs and a corrected output and arranged to derive corrected output signals from the digital intermediate signals under correction of errors according to the error correcting code.

5. An integrated circuit according to claim 4, comprising an error correction bit generator circuit and a further error correction circuit, the error correction circuit having an output coupled to an input of the further error correction circuit, each section having a further intermediate output, the further intermediate output of all sections except the first one of the sections being coupled to the input of the further error correction circuit, the error correction bit generator circuit having an output coupled to the further error correcting circuit, the error correction bit generator circuit being designed so that, when the sections operate properly, signals coupled to the input of the further error correcting circuit from the error correction bit generator circuit, the error correcting circuit and the further intermediate outputs in combination form a vector in a further error correcting code, not being a repetition code, the further error correction circuit being arranged to derive corrected output signals from the signals coupled to its inputs, under correction of errors according to the further error correcting code.

6. An integrated circuit according to claim 4, a first one of the sections having a plurality of intermediate outputs coupled to common logic gates in the first one of the sections, said error correction circuit being one of a plurality of error correction circuits comprised in the integrated circuit, each intermediate output of the plurality of intermediate outputs being coupled to a respective one of the plurality of error correcting circuits in combination with outputs from other ones of said sections, the sections being designed so that, when the sections operate properly, for each of the error correction circuits signals coupled to that error correction circuits in combination form a vector in a respective error correcting code, not being a repetition code, each error correction circuit being arranged to derive corrected output signals from the signals coupled to its inputs, under correction of errors according to its respective error correcting code.

7. An integrated circuit according to claim 4 comprising a first and a second layer of error correction circuitry, each layer containing a plurality of error correction circuits, each section having a plurality of intermediate outputs, each coupled to respective ones of the error correction circuits in the first layer, the error correction circuits in the first layer each having a plurality of outputs coupled to respective ones of the error correction circuits in the second layer, the sections being designed so that, when the integrated circuit operates correctly, combined input signals of each error correction circuit of the pluralities of error correction circuits each form a vector in a respective error correcting code, not being a repetition code, each error correction circuit being arranged to derive corrected output signals from the signals coupled to its inputs, under correction of errors according to its respective error correcting code.

8. An integrated circuit according to claim 7, wherein the error correction circuits of the first layer have output bits, each output bit depending on a single corresponding input bit when the sections operate correctly, the inputs of each error correction circuit of the second layer receiving output bits that depend on input bits coupled to the error correction circuits of the first layer from mutually different ones of the sections.

9. An integrated circuit according to claim 8, wherein the output bits of the each error correction circuit of the first layer are coupled to respective ones of the error correction circuits in the second layer.

10. An integrated circuit according to claim 4, wherein a first part of the digital intermediate signals are information signals, each output signal depending on a respective one of the first part of the information signals only when the sections operate without error, the logic relation between the input signals and the information signals implementing a further non-invertible combinatorial logic function, a second part of the signals being redundant correction signals for the information signals, corresponding to error correction bit signals computed from a result of the further non-invertible combinatorial logic function.

11. An integrated circuit according to claim 10, wherein the further non-invertible combinatorial logic function is non-linear, the error correcting code being linear, the error correction circuit correcting the intermediate signals by linear exclusive OR addition of corrections computed from the intermediate signals.

12. An integrated circuit according to claim 4, comprising a scan chain interface with a series of scan chain registers, each coupled between a respective one of the sections on one hand and the error correction circuit on the other hand.
